(19) United States
(12) Patent Application Publication
(10) Pub. No.: US 2008/0253481 A1
(43) Pub. Date: Oct. 16, 2008

(54) Method for computing the frequency of a signal from in-phase and quadrature components

(76) Inventors: Paul D. Rivkin, New Hartford, NY (US); Brian D. Moore, New Hartford, NY (US); Charles F. Estrella, Clinton, NY (US); Brian D. Bush, Rome, NY (US)

Correspondence Address: Michael J. Laquidari, Suite 100, 6780 Northern Boulevard, East Syracuse, NY, 13057, US

(21) Appl. No.: 11/735,493

(22) Filed: Apr. 16, 2007

(51) Int. Cl. H03K 9/00

(52) U.S. Cl. 375/316

(57) ABSTRACT

A novel method and apparatus for computing the phase derivative and also the frequency of a received signal from digital baseband In-Phase (I) and Quadrature (Q) samples is derived and implemented. The resulting method computes the phase derivative and frequency of a received signal from I and Q data directly without the intermediate problem of phase unwrapping required for computing the derivative of modulo-mapped phase. The apparatus is intended for use both in single channel systems performing digital frequency demodulation and in direction-finding systems computing differential phase across two channels.

### BACKGROUND OF THE INVENTION

1. Field of the Invention

The invention relates to an improved method of extracting instantaneous frequency information from a received signal. More specifically, the invention relates to a method and system for computing the phase derivative, which is proportional to the signal instantaneous frequency, from the in-phase and quadrature components of an input signal without the need for the interim step of phase unwrapping. The invention can also be used to compute differential phase between two signals across two channels.

2. Description of Related Art

The process of extracting frequency information from a signal is well-documented. Methods exist for accomplishing the frequency extraction using analog or digital processing or a combination of both, and the different methods provide varying levels of fidelity in terms of resolution in time, frequency and spectral power. In the fields of communications and military signal processing, there is a need for high fidelity measurements of signal frequency.

In the analog realm, an approach to deriving frequency information is with a superheterodyne receiver. In the superheterodyne receiver, a local oscillator (LO) is used to convert an incoming radiofrequency (RF) signal to a fixed intermediate frequency (IF) by the heterodyning (mixing) process. A single circuit tuned to the IF can then filter, amplify and otherwise process the signal. To sample frequency data, the LO is swept across the frequency range of interest, and the resulting amplitude at the output of the IF circuit can be sampled, for instance, to provide amplitude versus frequency. This process provides a spectral profile of the signal.

Other heterodyne techniques may include additional processing of the analog IF signal in order to produce in-phase and quadrature (I and Q) signal components. The I and Q components make it convenient to derive the instantaneous signal envelope and phase. The derivative of phase with respect to time provides a measure of frequency.

A typical implementation of an instantaneous frequency measurement receiver utilizes a crystal video receiver with the addition of a frequency sensing method. The frequency sensing may be accomplished by dividing the signal into two paths with different relative delays, then comparing the phase from each path. The phase difference is proportional to the carrier frequency.

A typical implementation for digital processing is shown in FIG. 1 and involves the following steps:
1. Analog-to-digital conversion 20 of an analog input signal 10 at a sampling rate fₛ that satisfies the Nyquist sample rate criterion,
2. Digital quadrature demodulation 30 to generate baseband in-phase (I) 40 and quadrature (Q) 50 signal components,
3. Computation of signal phase 80 and amplitude 70 from baseband 140 and Q 50 signal components, typically done using a coordinate rotation digital computer (CORDIC) routine 60,
4. Unwrapping 90 the phase to remove the modulo 2π discontinuities inherent in the arctangent function, and
5. Estimation of signal frequency 110 from the derivative 100 of adjacent samples of the unwrapped phase.

The CORDIC method is a well documented and well utilized digital signal processing technique in the field of communications and RF signal processing. The use of the CORDIC routine for fast digital trigonometric computations is known from the article “The CORDIC Trigonometric Computing Technique,” published in the IRE Transactions on Electronic Computers, September 1959 by J. E. Voider. The computations are effected via simple signal processing operations such as binary shifts, additions, subtractions and by calling constants from look-up tables. The CORDIC thus has a very simple and efficient circuit structure which in an integrated form requires comparatively little processing resources. In one mode of operation, the CORDIC operates in the so-called rotation mode in which mode a Cartesian (rectangular) coordinate representation is converted into a polar coordinate signal representation.

Examples of the utilization of the CORDIC routine are shown in literature. In Gerardus U.S. Pat. No. 5,230,011, the CORDIC is applied to achieve phase output. In Sullivan U.S. Pat. No. 7,020,190, the CORDIC is used as a means of accomplishing frequency translation, though direct computation of frequency is not shown.

The frequency computation process depicted in FIG. 1 necessitates the unwrapping 90 of the phase 80 prior to differentiation 100. The process of phase unwrapping is well documented, and it involves the detection and removal of discontinuities in the measured phase resulting from the modulo 2π characteristic of the arctangent function. An example of the phase-unwrapping problem is demonstrated in a recent US Patent Application by Puma, US2006/0115021. In Puma, a phase correction circuit (illustrated in FIG. 4 of US2006/0115021) is utilized to correct the modulo 2π discontinuity in the typical CORDIC output. Discontinuities typically found in the unwrapped phase are shown in FIG. 2 for a linear frequency modulated (LFM) signal 200 where the phase is constrained to modulo 2π and is centered at zero.

As another example, the phase for a constant frequency signal is shown in FIG. 3 in both wrapped 300 and unwrapped 310 forms. Note that the phase is linear for this constant frequency case. Here the impact of the modulus operator is more apparent where the limitation of a range of 2π 320 is shown for the wrapped phase 300. In FIG. 4 is shown the direct first-order difference of the wrapped phase 400 and the direct first-order difference of the unwrapped phase 410. For the wrapped phase 300, an approximate 2π discontinuity occurs in the derivative 400 where the phase wraps, which causes anomalous spikes 420 in the derivative.

Phase unwrapping requires additional logic in a demodulator design and is fairly straightforward for signals that are highly over sampled (fₛ>>2*BW, sample frequency is much greater than two times the signal bandwidth) and with a high signal to noise ratio (SNR). However, for near critically sampled signals (fₛ≈2*BW) with increased noise levels (lower SNR), the process can be prone to errors.

### BRIEF SUMMARY OF THE INVENTION

It is the object of this invention to provide a novel method and apparatus for computing the phase derivative and also the frequency of a signal from In-Phase (I) and Quadrature (Q) components of the signal. The resulting method computes frequency from I/Q data without the need for an interim step of phase unwrapping. The method is intended for use in either single channel systems performing digital frequency demodulation or in direction-finding systems computing differential phase across two channels.

### BRIEF DESCRIPTION OF THE DRAWINGS

FIG. 1 is an illustration of a typical digital frequency demodulation process.

FIG. 2 is an illustration of the modulo 2π (wrapped) phase of a linear frequency modulated signal.

FIG. 3 is an illustration of a linear phase signal, showing both the wrapped and unwrapped representation of phase.

FIG. 4 is an illustration showing the discontinuities of the derivative of wrapped linear phase compared to the continuous derivative of unwrapped linear phase.

FIG. 5 is an illustration of the complex vector representation of two signal samples.

FIG. 6 is an illustration of a circuit to accomplish the phase derivative computation for a single channel.

FIG. 7 is an illustration of a circuit to accomplish the two channel differential phase computation.

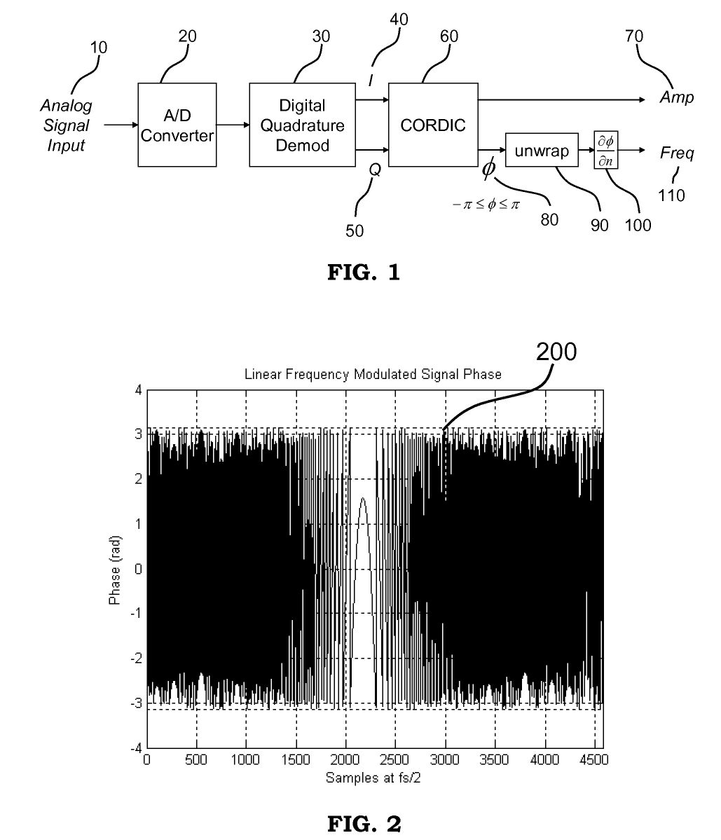

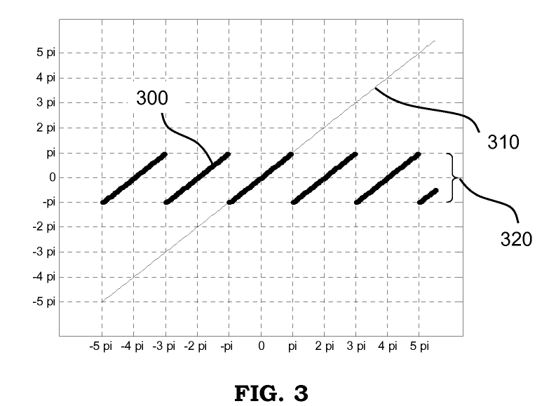

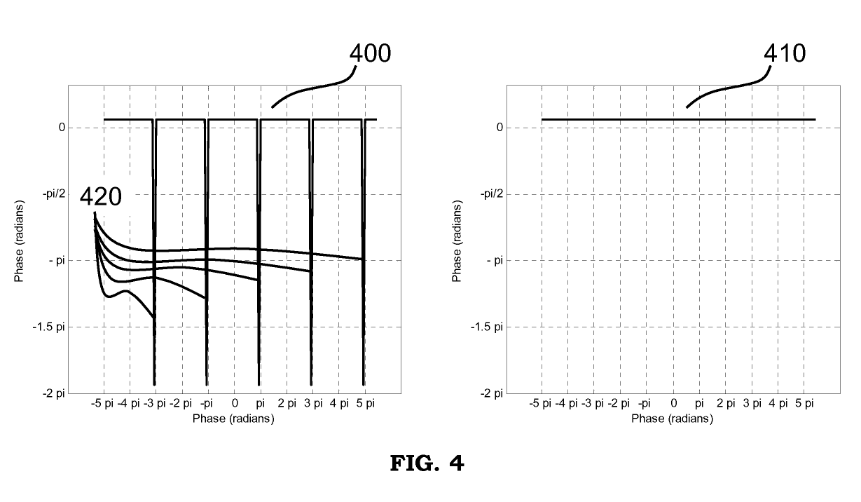

### DETAILED DESCRIPTION OF THE INVENTION

The present invention will now be described. The present invention provides a novel method for computing frequency directly from phase samples without the need for an interim step of phase unwrapping.

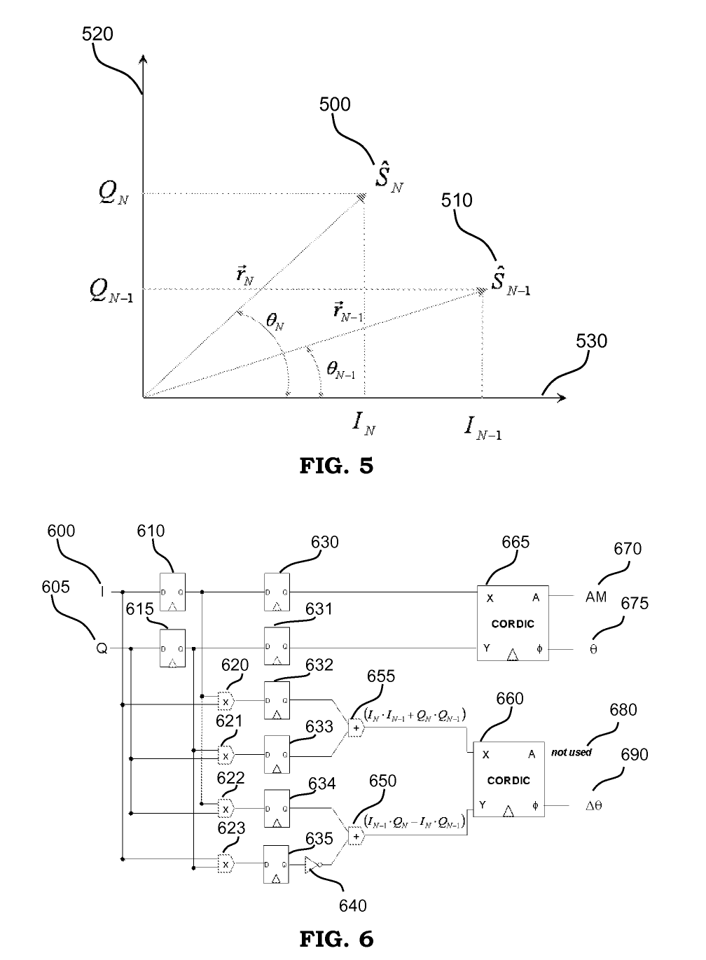

Let two complex vectors Ŝ_{N} 500 and Ŝ_{N-1} 510 represent consecutive I/Q samples, as shown in FIG. 5. The complex vectors are given by

$$\begin{matrix}{\hat{S}}_{N} = {r}_{N} \cdot {e}^{j ( {θ}_{N} )} \\ and & E \text{-} 1 \\ {\hat{S}}_{N - 1} = {r}_{N - 1} \cdot {e}^{j ( {θ}_{N - 1} )} & E \text{-} 2\end{matrix}$$

The product of the first vector with the conjugate of the second vector yields

$${\hat{S}}_{N} \cdot {\hat{S}}_{N - 1}^{*} = {r}_{N} \cdot {r}_{N - 1} \cdot {e}^{j ( {θ}_{N} - {θ}_{N - 1} )} \qquad E \text{-} 3$$

The exponent argument θ_{N}−θ_{N-1} is the phase difference Δθ between the consecutive samples. To compute it, the consecutive samples are expressed in rectangular form as

Ŝ_{N}=(I_{N}+j·Q_{N}) E-4

and

Ŝ*_{N-1}=(I_{N-1}−j·Q_{N-1}) E-5

and multiplied to yield

Ŝ_{N}·Ŝ*_{N-1}=(I_{N}+j·Q_{N})·(I_{N-1}−j·Q_{N-1}) E-6

Expanding Equation E-6 yields

Ŝ_{N}·Ŝ*_{N-1}=(I_{N}·I_{N-1}+Q_{N}·Q_{N-1})+j(I_{N-1}·Q_{N}−I_{N}·Q_{N-1}) E-7

The corresponding differential phase between samples can be computed from Equation E-7 employing the arc tangent function:

$${θ}_{N} - {θ}_{N - 1} = {tan}^{- 1} ( \frac{{I}_{N - 1} \cdot {Q}_{N} - {I}_{N} \cdot {Q}_{N - 1}}{{I}_{N} \cdot {I}_{N - 1} + {Q}_{N} \cdot {Q}_{N - 1}} ) \qquad E \text{-} 8$$

The expression for differential phase given in Equation E-8 can be implemented using a CORDIC algorithm. The CORDIC algorithm is a commonly used digital signal processing technique used to implement several functions, including rectangular to polar conversion. The CORDIC therefore serves as a means of computing the phase angle of the equivalent polar coordinate representation of the rectangular coordinates given inputs that represent the abscissa 530 rectangular coordinate and the ordinate 520 rectangular coordinate. The present invention relates to modifying the inputs applied so that a means of computing the phase angle from rectangular coordinates yields the phase derivative rather than the phase. This modification of inputs when applied to, for example, a CORDIC routine results in the computation of the differential phase Δθ between adjacent samples.

An apparatus devised with logic circuitry to compute the differential phase between adjacent I/Q samples is shown in FIG. 6. The typical implementation of the CORDIC 665 utilizing the quadrature inputs of the I 600 and Q 605 signals is shown, where the CORDIC 665 outputs are signal amplitude 670 and phase 675. The delay registers 630 and 631 are used for time alignment of the outputs of CORDIC 660 and CORDIC 665. In order to obtain the phase derivative and signal frequency, the phase output 675 of the CORDIC 665 must first be unwrapped to remove any modulo 2π discontinuities.

An apparatus for computing the signal frequency directly without the interim step of phase unwrapping is also shown in FIG. 6 and is implemented using a separate CORDIC 660. The apparatus consists of one inverter 640, four multipliers 620, 621, 622 and 623, two adders 650 and 655, and eight delay registers 610, 615, 632, 633, 634 and 635, provides the instantaneous differential phase 690, which is proportional to frequency, per clock cycle without the need for phase unwrapping. The other output 680 of the CORDIC 660 is not used.

The device shown in FIG. 6 utilizes the sampled I 600 and Q 605 signal components as input. Delay registers 610 and 615 are used to generate a one sample delay in each the I 600 and Q 605 data. Multiplier 620 multiplies the I 600 data with the one sample delayed I data and passes the result to delay register 632. Multiplier 621 multiplies the Q 605 data with the one sample delayed Q data and passes the result to delay register 633. Multiplier 622 multiplies the Q 605 data with the one sample delayed I data and passes the result to delay register 634. Multiplier 623 multiplies the I 600 data with the one sample delayed Q data and passes the result to delay register 635.

The output of delay registers 632 and 633 are combined by adder 655. The output of delay register 635 is inverted by inverter 640 and combined with the output of delay register 634 by adder 650. The combined outputs of adders 650 and 655 are the modified inputs to the CORDIC 660. These modified inputs are what produce the instantaneous phase derivative 690 at the phase output of the CORDIC 660. Frequency is easily computed from the phase derivative by scaling the phase derivative by a scale factor proportional to the sample rate of the input signal.

While the CORDIC has been shown here as a preferred implementation for computing the phase angle of the equivalent polar coordinate representation of the rectangular coordinates given inputs that represent the abscissa 530 rectangular coordinate and the ordinate 520 rectangular coordinate, it should be apparent to those skilled in the art that a number of means could be applied to compute this phase angle, including the use of a look-up table or some other form of arctangent calculation.

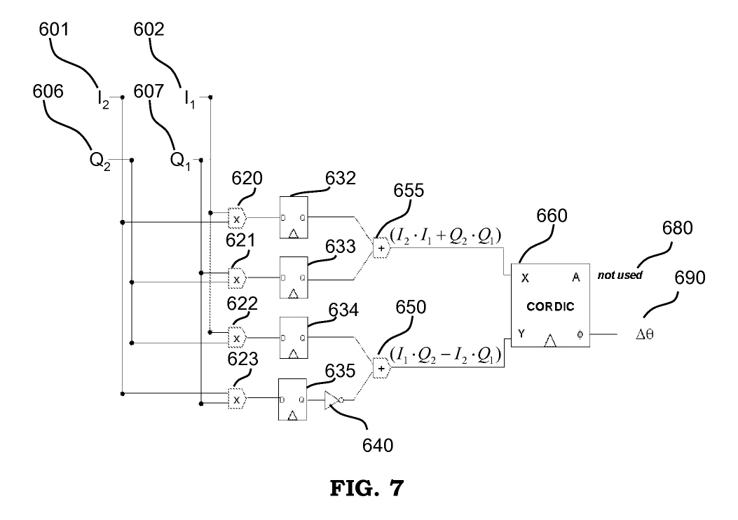

In FIG. 7, a circuit similar to that described in FIG. 6 is used to compute the differential phase between two channels. The input in-phase 600 and quadrature 605 signals and the delay registers 610 and 615 are replaced by channel two in-phase 601 and quadrature 606 sampled signals and channel one in-phase 602 and quadrature 607 sampled signals.

Multiplier 620 multiplies the channel one I 602 data with the channel two I data 601 and passes the result to delay register 632. Multiplier 621 multiplies the channel one Q 607 data with the channel two Q 606 data and passes the result to delay register 633. Multiplier 622 multiplies the channel one I 602 data with the channel two Q 606 data and passes the result to delay register 634. Multiplier 623 multiplies the channel two I 601 data with the channel one Q 607 data and passes the result to delay register 635.

The output of delay registers 632 and 633 are combined by adder 655. The output of delay register 635 is inverted by inverter 640 and combined with the output of delay register 634 by adder 650. The combined outputs of adders 650 and 655 are the modified inputs to the CORDIC 660. These modified inputs are what produce the differential phase 690 between the two channels at the phase output of the CORDIC 660.

It should be understood that the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

What is claimed is:

1. A method for computing the phase derivative of a received signal, the method comprising the steps of:
receiving time sampled in-phase and quadrature signal samples;
multiplying the current sample of the sampled in-phase signal with a sample of the in-phase signal delayed by one time interval to produce a first multiplier output;
multiplying the current sample of the sampled quadrature signal with a sample of the quadrature signal delayed by one time interval to produce a second multiplier output;
multiplying the current sample of the sampled quadrature signal with a sample of the in-phase signal delayed by one time interval to produce a third multiplier output;
multiplying the current sample of the sampled in-phase signal with a sample of the quadrature signal delayed by one time interval to produce a fourth multiplier output;
inverting the fourth multiplier output to produce an inverted fourth multiplier output;
adding the first multiplier output and the second multiplier output to produce a first adder output;
adding the third multiplier output and the inverted fourth multiplier output to produce a second adder output; and
computing the phase derivative by computing the phase angle of the equivalent polar coordinate representation of the rectangular coordinates where the first adder output represents the abscissa rectangular coordinate and the second adder output represents the ordinate rectangular coordinate.

2. The method of claim 1, where the means of computing the phase angle of the equivalent polar coordinate representation of the rectangular coordinates includes the steps of:
computing a ratio of the second adder output divided by the first adder output; and
calculating the arctangent function of said ratio.

3. The method of claim 1, where the means of computing the phase angle of the equivalent polar coordinate representation of the rectangular coordinates is a CORDIC routine in the rotation mode.

4. The method of claim 1, where the phase derivative is scaled by the sample rate of the sampled in-phase and quadrature signal components to compute the signal instantaneous frequency.

5. A method for computing the differential phase between two received signals, the method comprising the steps of:
receiving time sampled channel one in-phase and channel one quadrature signal samples;
receiving time sampled channel two in-phase and channel two quadrature signal samples;
multiplying the channel one in-phase signal with the channel two in-phase signal to produce a first multiplier output;
multiplying the channel one quadrature signal with the channel two quadrature signal to produce a second multiplier output;
multiplying the channel one in-phase signal with the channel two quadrature signal to produce a third multiplier output;
multiplying the channel two in-phase signal with the channel one quadrature signal to produce a fourth multiplier output;
inverting the fourth multiplier output to produce an inverted fourth multiplier output;
adding the first multiplier output and the second multiplier output to produce a first adder output;
adding the third multiplier output and the inverted fourth multiplier output to produce a second adder output; and
computing the differential phase by computing the phase angle of the equivalent polar coordinate representation of the rectangular coordinates where the first adder output represents the abscissa rectangular coordinate and the second adder output represents the ordinate rectangular coordinate.

6. The method of claim 5, where the means of computing the phase angle of the equivalent polar coordinate representation of the rectangular coordinates includes the steps of:
computing a ratio of the second adder output divided by the first adder output; and
calculating the arctangent function of said ratio.

7. The method of claim 5, where the means of computing the phase angle of the equivalent polar coordinate representation of the rectangular coordinates is a CORDIC routine in the rotation mode.

8. An apparatus for computing the phase derivative of a received signal comprising:
a first multiplier that multiplies the current sample of a sampled in-phase signal component with a sample of the in-phase signal component delayed by one time interval to produce a first multiplier output;
a second multiplier that multiplies the current sample of a sampled quadrature signal component with a sample of the quadrature signal component delayed by one time interval to produce a second multiplier output;
a third multiplier that multiplies the current sample of the sampled quadrature signal component with a sample of the in-phase signal component delayed by one time interval to produce a third multiplier output;
a fourth multiplier that multiplies the current sample of the sampled in-phase signal component with a sample of the quadrature signal component delayed by one time interval to produce a fourth multiplier output;
an inverter that inverts the fourth multiplier output to produce an inverted fourth multiplier output;
a first adder that adds the first multiplier output with the second multiplier output to produce a first adder output;
a second adder that adds the third multiplier output with the inverted fourth multiplier output to produce a second adder output;
a means of computing the phase derivative by computing the phase angle of the equivalent polar coordinate representation of the rectangular coordinates where the first adder output represents the abscissa rectangular coordinate and the second adder output represents the ordinate rectangular coordinate.

9. The apparatus of claim 8, where the means of computing the phase angle of the equivalent polar coordinate representation of the rectangular coordinates comprises:
a means of computing a ratio of the second adder output divided by the first adder output; and
a means of calculating the arctangent function of said ratio.

10. The apparatus of claim 8, where the means of computing the phase angle of the equivalent polar coordinate representation of the rectangular coordinates is a CORDIC routine in the rotation mode.

11. The apparatus of claim 8, further comprising:
a means of scaling the phase derivative by the sample rate of the sampled in-phase and quadrature signal components to produce the signal instantaneous frequency.

12. An apparatus for computing the differential phase between two received signals comprising:
a first multiplier that multiplies a channel one in-phase signal with a channel two in-phase signal to produce a first multiplier output;
a second multiplier that multiplies a channel one quadrature signal with a channel two quadrature signal to produce a second multiplier output;
a third multiplier that multiplies the channel one in-phase signal with the channel two quadrature signal to produce a third multiplier output;
a fourth multiplier that multiplies the channel two in-phase signal with the channel one quadrature signal to produce a fourth multiplier output;
an inverter that inverts the fourth multiplier output to produce an inverted fourth multiplier output;
a first adder that adds the first multiplier output with the second multiplier output to produce a first adder output;
a second adder that adds the third multiplier output with the inverted fourth multiplier output to produce a second adder output;
a means of computing the differential phase by computing the phase angle of the equivalent polar coordinate representation of the rectangular coordinates where the first adder output represents the abscissa rectangular coordinate and the second adder output represents the ordinate rectangular coordinate.

13. The apparatus of claim 12, where the means of computing the phase angle of the equivalent polar coordinate representation of the rectangular coordinates comprises:
a means of computing a ratio of the second adder output divided by the first adder output; and
a means of calculating the arctangent function of said ratio.

14. The apparatus of claim 12, where the means of computing the phase angle of the equivalent polar coordinate representation of the rectangular coordinates is a CORDIC routine in the rotation mode.
